(19) United States
(12) Patent Application Publication
(10) Pub. No.: US 2024/0322048 A1
(43) Pub. Date: Sep. 26, 2024

(54) INTERGRATED CIRCUIT DEVICES

(71) Applicant: Samsung Electronics Co., Ltd., Suwon-si (KR)

(72) Inventors: Kyunghwan LEE, Suwon-si (KR); Jeonil LEE, Suwon-si (KR); Minhee CHO, Suwon-si (KR); Daweon HA, Suwon-si (KR)

(73) Assignee: Samsung Electronics Co., Ltd., Suwon-si (KR)

(21) Appl. No.: 18/606,081

(22) Filed: Mar. 15, 2024

(30) Foreign Application Priority Data
Mar. 24, 2023 (KR) 10-2023-0039200
May 11, 2023 (KR) 10-2023-0061260

(51) Int. Cl. H01L 29/792; H10B 12/00

(52) U.S. Cl. CPC H01L 29/7926; H10B 12/482; H10B 12/485; H10B 12/488

(57) ABSTRACT

Provided is an integrated circuit device including a source line extending in a first horizontal direction on a substrate, a channel layer extending in a vertical direction, disposed on the source line, and having a first sidewall and a second sidewall, a trapping layer on the first sidewall of the channel layer and including an oxide semiconductor, a word line on at least one sidewall of the trapping layer and extending in a second horizontal direction crossing the first horizontal direction, a gate insulation layer between the at least one sidewall of the trapping layer and the word line, and a bit line electrically connected to the channel layer and extending in the first horizontal direction, wherein the channel layer has a first bandgap energy, and the trapping layer has a second bandgap energy that is greater than the first bandgap energy.

### CROSS-REFERENCE TO RELATED APPLICATIONS

This application is based on and claims priority under 35 U.S.C. § 119 to Korean Patent Application Nos. 10-2023-0039200, filed on Mar. 24, 2023, and 10-2023-0061260, filed on May 11, 2023, in the Korean Intellectual Property Office, the disclosures of which are incorporated by reference herein in their entirety.

### BACKGROUND

The inventive concepts relate to integrated circuit devices, and more particularly, to integrated circuit devices including a capacitor-less memory.

As integrated circuit devices are being downscaled, sizes of individual micro circuit patterns for implementing integrated circuit devices are being further reduced. In particular, as the height of a capacitor included in a dynamic random-access memory (DRAM) device increases, the difficulty of a capacitor formation process increases, and accordingly, refresh is needed to resolve the problem of a leakage current through a capacitor. Therefore, a capacitor-less DRAM device consisting of a single transistor without including a capacitor has been proposed.

### SUMMARY

The inventive concepts provide integrated circuit devices including a capacitor-less memory with improved retention characteristics.

According to an aspect of the inventive concepts, an integrated circuit device includes a source line extending in a first horizontal direction on a substrate, a channel layer extending in a vertical direction perpendicular to a top surface of the substrate, the channel layer being on the source line, and having a first sidewall and a second sidewall, a trapping layer on the first sidewall of the channel layer and including an oxide semiconductor, a word line on at least one sidewall of the trapping layer and extending in a second horizontal direction crossing the first horizontal direction, a gate insulation layer between the at least one sidewall of the trapping layer and the word line, and a bit line electrically connected to the channel layer and extending in the first horizontal direction, wherein the channel layer has a first bandgap energy, and the trapping layer has a second bandgap energy that is greater than the first bandgap energy.

According to another aspect of the inventive concepts, an integrated circuit device includes a source line extending in a first horizontal direction on a substrate, a source region on the source line and including a p-type impurity, a channel layer extending from the source region in a vertical direction perpendicular to a top surface of the substrate, the channel layer having a first sidewall and a second sidewall facing each other, a trapping layer on the first sidewall of the channel layer and on a top surface of the source region, the trapping layer including an oxide semiconductor, a word line on the first sidewall of the channel layer and on the top surface of the source region, the trapping layer and a gate insulation layer being between the channel layer and the word line and between the source region and the word line, a drain region on a top surface of the channel layer and including a p-type impurity, and a bit line electrically connected to the drain region and extending in the first horizontal direction, wherein a valence band offset between a valence band level of the channel layer and a valence band level of the trapping layer is 0.5 eV or greater.

According to another aspect of the inventive concepts, an integrated circuit device includes a source line extending in a first horizontal direction on a substrate, a mold insulation layer on the substrate to cover the source line and having an opening, a source region in the opening of the mold insulation layer, the source region being on a top surface of the source line, and the source region including a p-type impurity, a channel layer in the opening of the mold insulation layer, the channel layer extending from the source region in a vertical direction perpendicular to a top surface of the substrate, the channel layer having a first sidewall and a second sidewall facing each other, the second sidewall being in contact with the mold insulation layer, a trapping layer in the opening of the mold insulation layer, the trapping layer being on the first sidewall of the channel layer and on a top surface of the source region, the trapping layer including an oxide semiconductor, a word line in the opening of the mold insulation layer, the word line being on the first sidewall of the channel layer and on the top surface of the source region, the trapping layer and a gate insulation layer being between the channel layer and the word line and between the source region and the word line, a drain region in the opening of the mold insulation layer, the drain region being on a top surface of the channel layer, the drain region including a p-type impurity, and a bit line electrically connected to the drain region and extending in the first horizontal direction, wherein the channel layer includes polysilicon, silicon germanium, or a 2-dimensional material, and the trapping layer includes at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), or tin oxide (SnₓO).

### BRIEF DESCRIPTION OF THE DRAWINGS

Example embodiments of the inventive concepts will be more clearly understood from the following detailed description taken in conjunction with the accompanying drawings in which:

FIG. 1 is a circuit diagram showing an integrated circuit device according to an example embodiment;

FIG. 2 is a layout diagram showing an integrated circuit device according to an example embodiment;

FIG. 3 is a perspective view of a portion of a cell array area of FIG. 2;

FIG. 4 is a cross-sectional view taken along a line A1-A1′ of FIG. 3;

FIG. 5 is a schematic diagram showing a band diagram when no bias is applied, in a program operation, and in an erase operation of an integrated circuit device, respectively, according to an example embodiment;

FIG. 6 is a graph schematically showing a voltage-current curve of an integrated circuit device according to an example embodiment;

FIG. 7 is a cross-sectional view of an integrated circuit device according to an example embodiment;

FIG. 8 is a cross-sectional view of an integrated circuit device according to an example embodiment;

FIG. 9 is a cross-sectional view of an integrated circuit device according to an example embodiment;

FIG. 10 is a cross-sectional view of an integrated circuit device according to an example embodiment;

FIG. 11 is a perspective view of an integrated circuit device according to an example embodiment;

FIG. 12 is a perspective view of an integrated circuit device according to an example embodiment;

FIG. 13 is a perspective view of an integrated circuit device according to an example embodiment; and

FIGS. 14A to 20B are schematic views of a method of manufacturing an integrated circuit device, according to an example embodiment. In detail, FIGS. 14A, 15A, 16A, 17A, 18A, 19A, and 20A are cross-sectional views of structures formed during a manufacturing process taken along a line A1-A1′ of FIG. 3, and FIGS. 14B, 15B, 16B, 17B, 18B, 19B, and 20B are top views of FIGS. 14A, 15A, 16A, 17A, 18A, 19A, and 20A, respectively.

### DETAILED DESCRIPTION

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

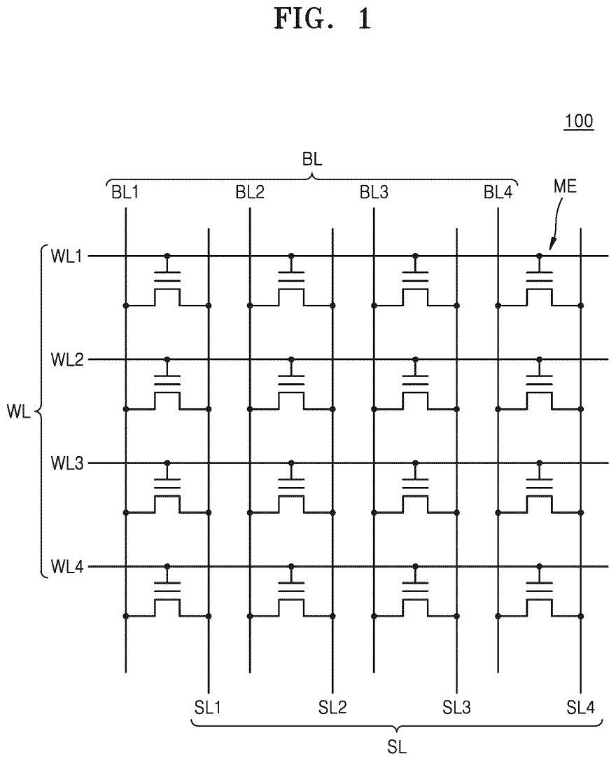

FIG. 1 is a circuit diagram showing an integrated circuit device 100 according to an example embodiment.

Referring to FIG. 1, the integrated circuit device 100 may include a plurality of memory units ME arranged between a plurality of word lines WL and a plurality of bit lines BL. The plurality of memory units ME may include charge-trapping type transistors. For example, the plurality of memory units ME may be arranged at intersections of first to fourth word lines WL1, WL2, WL3, and WL4 and first to fourth bit lines BL1, BL2, BL3, and BL4. A gate terminal of a memory unit ME may be connected to a word line WL, a drain terminal of the memory unit ME may be connected to a bit line BL, and a source terminal of the memory unit ME may be connected to a source line SL. According to some example embodiments, first to fourth source lines SL1, SL2, SL3, and SL4 may extend in parallel with the first to fourth bit lines BL1, BL2, BL3, and BL4, but the inventive concepts are not limited thereto. The plurality of memory units ME may include charge-trapping type transistors, and the integrated circuit device 100 may be a capacitor-less dynamic random-access memory (DRAM) device including a single transistor arranged in a cross-point type.

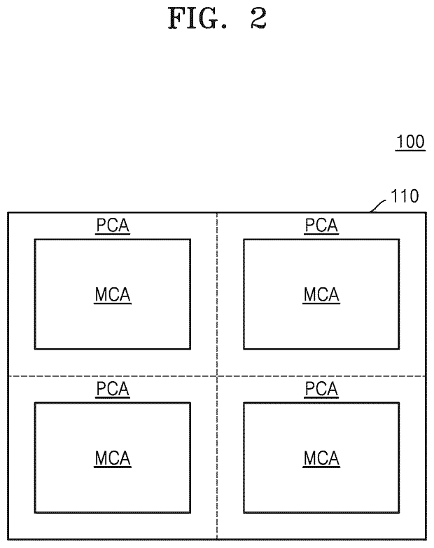

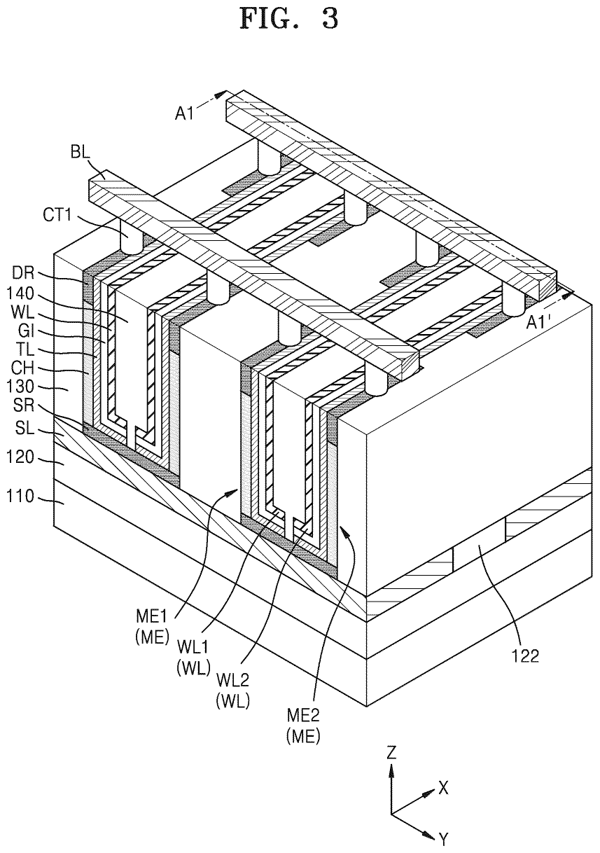

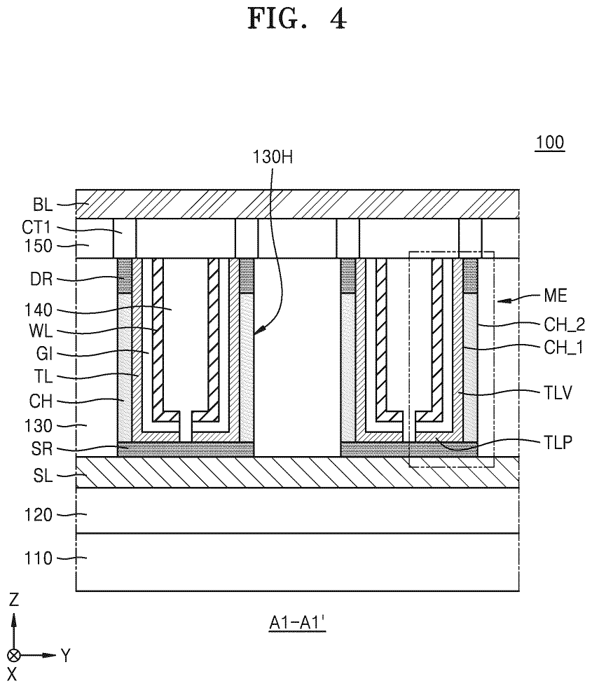

FIG. 2 is a layout diagram showing the integrated circuit device 100 according to an example embodiment. FIG. 3 is a perspective view of a portion of a cell array area MCA of FIG. 2. FIG. 4 is a cross-sectional view taken along a line A1-A1′ of FIG. 3.

Referring to FIGS. 2 to 4, the integrated circuit device 100 may include a substrate 110 including the cell array area MCA and a peripheral circuit area PCA. According to some example embodiments, the cell array area MCA may be a memory cell area of a capacitor-less integrated circuit device, and the peripheral circuit area PCA may be a core area or a peripheral circuit area of the capacitor-less integrated circuit device. For example, the peripheral circuit area PCA may include a peripheral circuit transistor (not shown) for transmitting a signal and/or power to a memory cell array included in the cell array area MCA. According to some example embodiments, the peripheral circuit transistor (not shown) may constitute various circuits like a command decoder, control logic, an address buffer, a row decoder, a column decoder, a sense amplifier, and a data input/output circuit.

As shown in FIG. 3, on the cell array area MCA of the substrate 110, the plurality of word lines WL extending in a first horizontal direction X, the plurality of bit lines BL extending in a second horizontal direction Y, and a plurality of source lines SL extending in the second horizontal direction Y may be arranged. The plurality of memory units ME may be arranged at intersections of the plurality of word lines WL and the plurality of bit lines BL. The plurality of memory units ME may include charge-trapping type transistors or charge-trapping type memory devices.

According to some example embodiments, the plurality of memory units ME may include a first memory unit ME1 and a second memory unit ME2 arranged symmetrically with each other, and a first word line WL1 and a second word line WL2 may be arranged apart from each other between the first memory unit ME1 and the second memory unit ME2.

According to some example embodiments, when the width of each of the plurality of source lines SL is defined as IF, a unit area for forming one memory unit ME may be 4F². Because one memory unit ME may be a cross-point type that needs a relatively small unit area, the integration of the integrated circuit device 100 may be improved.

As shown in FIG. 4, a lower insulation layer 120 may be disposed on the substrate 110. The substrate 110 may include silicon, for example, monocrystalline silicon, polycrystalline silicon, or amorphous silicon. In some other example embodiments, the substrate 110 may include at least one selected from among Ge, SiGe, SiC, GaAs, InAs, and InP. According to some example embodiments, the substrate 110 may include a conductive region, for example, a well doped with an impurity or a structure doped with an impurity. The lower insulation layer 120 may include an oxide film, a nitride film, or a combination thereof.

The source line SL extending in the second horizontal direction Y may be disposed on the lower insulation layer 120. According to some example embodiments, the source line SL may include doped polysilicon, for example, polysilicon doped with a p-type impurity. According to other example embodiments, the source line SL may include Ti, TiN, Ta, TaN, Mo, Ru, W, WN, Co, Ni, TiSi, TiSiN, WSi, WSiN, TaSi, TaSiN, RuTiN, CoSi, NiSi, or a combination thereof. A first insulation layer 122 may be disposed on the lower insulation layer 120 to cover sidewalls of the source line SL and have a top surface disposed on the same plane as the source line SL.

A mold insulation layer 130 may be disposed on the source line SL and the first insulation layer 122. The mold insulation layer 130 may include a plurality of openings 130H. The mold insulation layer 130 may include an oxide layer, a nitride layer, a low-k dielectric layer, or a combination thereof.

Two memory units ME may be disposed in each of the plurality of openings 130H of the mold insulation layer 130. The two memory units ME disposed in one opening 130H may have symmetrical shapes with respect to each other. According to some example embodiments, one opening 130H may include a first sidewall and a second sidewall facing each other, and the first memory unit ME1 disposed on the first sidewall of the opening 130H and the second memory unit ME2 disposed on the second sidewall of the opening 130H may have symmetrical shapes with respect to the center of the opening 130H.

The plurality of memory units ME may each include a source region SR, a channel layer CH, a trapping layer TL, and a gate insulation layer GI arranged in the plurality of openings 130H.

The source region SR may be disposed at the bottom of the opening 130H of the mold insulation layer 130 and may be disposed on the top surface of the source line SL. The source region SR may include at least one of polysilicon doped with a p-type impurity, silicon germanium doped with a p-type impurity, or a 2-dimensional material doped with a p-type impurity (e.g., hexagonal boron nitride, transition metal dichalcogenide, or graphene).

The channel layer CH may be disposed on the top surface of the source region SR and extend in the vertical direction Z. The channel layer CH may include a first sidewall CH_1 and a second sidewall CH_2, the trapping layer TL may be disposed on the first sidewall CH_1 of the channel layer CH, and the mold insulation layer 130 may be disposed on the second sidewall CH_2 of the channel layer CH. The channel layer CH may include at least one of polysilicon, silicon germanium, or a 2-dimensional material (e.g., hexagonal boron nitride, a transition metal dichalcogenide, or graphene).

A drain region DR may be disposed on the top surface of the channel layer CH. One sidewall of the drain region DR may contact the mold insulation layer 130 and the other sidewall of the drain region DR may contact the trapping layer TL. The drain region DR may include at least one of polysilicon doped with a p-type impurity, silicon germanium doped with a p-type impurity, or a 2-dimensional material doped with a p-type impurity (e.g., hexagonal boron nitride, a transition metal dichalcogenide, or graphene).

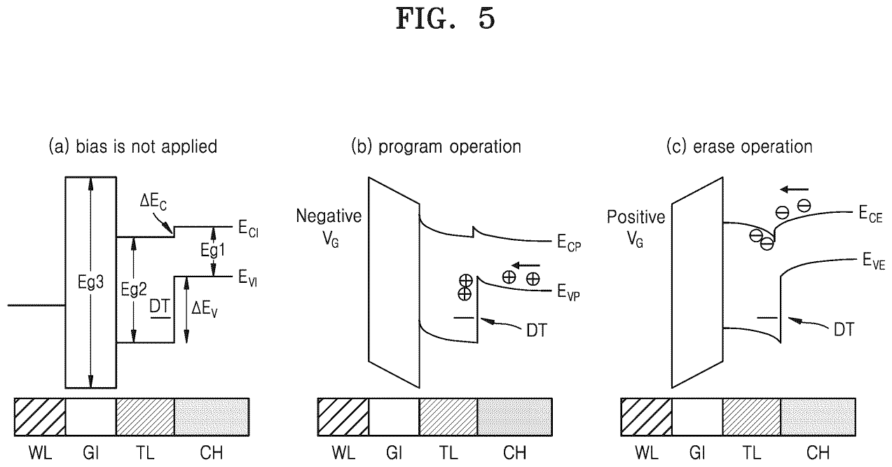

The trapping layer TL may be disposed on the first sidewall CH_1 of the channel layer CH and on the source region SR. According to some example embodiments, the trapping layer TL may include an oxide semiconductor. The trapping layer TL may be a data storage layer in which holes supplied from the channel layer CH may be trapped when the memory unit ME is in a programmed state. According to some example embodiments, the trapping layer TL may include a material having a greater bandgap energy than the channel layer CH. For example, as schematically shown in FIG. 5, the channel layer CH may have a first bandgap energy Eg1 and the trapping layer TL may have a second bandgap energy Eg2, wherein the second bandgap energy Eg2 is greater than the first bandgap energy Eg1.

According to some example embodiments, the trapping layer TL may include a material having a valence band offset ΔE_{V} that is greater than a conduction band offset ΔE_{C} with the channel layer CH. Here, the conduction band offset ΔE_{C} refers to the difference between the conduction band level of the channel layer CH and the conduction band level of the trapping layer TL, and the valence band offset ΔE_{V} refers to the difference between the valence band level of the channel layer CH and the valence band level of the trapping layer TL. According to some example embodiments, the valence band offset ΔE_{V} may be 0.5 eV or greater. According to some example embodiments, the valence band offset ΔE_{V} may be 1.0 eV or greater or may be 2.0 eV or greater. The valence band offset ΔE_{V} may have a sufficiently large value to use the trapping layer TL as a charge trapping unit (e.g., a hole trapping unit) by storing holes by using a deep trap level DT (refer to FIG. 5) inside the trapping layer TL.

According to some example embodiments, the trapping layer TL may include at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), or tin oxide (SnₓO). According to some example embodiments, in addition to the above-stated materials, the trapping layer TL may include an oxide semiconductor material having a bandgap energy greater than that of silicon.

According to some example embodiments, the trapping layer TL may include a vertical extension TLV contacting the first sidewall CH_1 of the channel layer CH and extending in the vertical direction Z and a horizontal extension TLP disposed on the source region SR. As shown in FIG. 4, the top surface of the vertical extension TLV of the trapping layer TL may be at the same level as the top surface of the drain region DR. As the trapping layer TL includes the vertical extension TLV and the horizontal extension TLP, the trapping layer TL may have an L-shaped vertical cross-section as shown in FIG. 4.

According to some example embodiments, as shown in FIG. 3, the trapping layer TL may extend in the first horizontal direction X and contact first sidewalls CH_1 of a plurality of channel layers CH arranged to be spaced apart from each other in the first horizontal direction X. According to other example embodiments, unlike as shown in FIG. 3, a plurality of trapping layers TL may be formed and arranged to be spaced apart from each other in the first horizontal direction X in correspondence to the plurality of channel layers CH arranged to be spaced apart from each other in the first horizontal direction X, respectively.

The gate insulation layer GI and a word line WL may be sequentially disposed on a sidewall of the trapping layer TL. The gate insulation layer GI and the word line WL may extend in the first horizontal direction X and may have an L-shaped vertical cross-section.

According to some example embodiments, the gate insulation layer GI may include at least one selected from a high-k dielectric material and a ferroelectric material having a dielectric constant higher than that of silicon oxide. According to some example embodiments, the gate insulation layer GI may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), and lead scandium tantalum oxide (PbScTaO).

According to some example embodiments, the word line WL may include Ti, TiN, Ta, TaN, Mo, Ru, W, WN, TiSiN, WSiN, polysilicon, or a combination thereof.

A filling insulation layer 140 may be disposed between two word lines WL arranged in the opening 130H of the mold insulation layer 130. According to some example embodiments, the filling insulation layer 140 may be formed as a stacked structure of a plurality of insulation layers. According to some example embodiments, the filling insulation layer 140 may include an insulation liner, which contacts the word line WL and includes a first insulation material, and an insulation layer, which does not directly contact the word line WL, fills the space between two word lines WL, and includes a second insulation material that is different from the first insulation material.

An upper insulation layer 150 may be disposed on the mold insulation layer 130 to cover the memory unit ME, the word line WL, and the filling insulation layer 140. The bit line BL extending in the second horizontal direction Y may be disposed on the upper insulation layer 150, and a bit line contact CT1 may penetrate through the upper insulation layer 150 and be disposed between the bit line BL and the drain region DR. For example, the bit line BL and the bit line contact CT1 may include Ti, TiN, Ta, TaN, W, WN, TiSiN, WSiN, polysilicon, or a combination thereof.

According to some example embodiments, the memory unit ME may constitute a cross-point type capacitor-less DRAM device. The memory unit ME may write, program, crase, or read data by trapping holes or electrons from the channel layer CH into the trapping layer TL by applying a gate voltage to the word line WL. According to some example embodiments, the memory unit ME may include the trapping layer TL having a relatively large valence band offset with respect to the channel layer CH and may store charges by trapping holes using the deep trap level inside the trapping layer TL. Therefore, the trapping layer TL may have an excellent memory window and may exhibit excellent retention characteristics at the same time. Furthermore, because a cross-point type capacitor-less DRAM device may be implemented, the degree of integration may be improved.

FIG. 5 is a schematic diagram showing a band diagram when no bias is applied, in a program operation, and in an erase operation of an integrated circuit, respectively, device according to an example embodiment.

Referring to FIG. 5, the channel layer CH may include a material having the first bandgap energy Eg1, and the trapping layer TL may have the second bandgap energy Eg2, wherein the second bandgap energy Eg2 is greater than the first bandgap energy Eg1. The gate insulation layer GI may include a material having a third bandgap energy Eg3 that is greater than the second bandgap energy Eg2.

As shown in a conduction band level E_{CI} in a flat band state in (a) of FIG. 5, the conduction band offset ΔE_{C} occurs at the interface between the trapping layer TL and the channel layer CH due to the difference between the conduction band level of the trapping layer TL and the conduction band level of the channel layer CH. The conduction band offset ΔE_{C} may have a relatively small value. According to some example embodiments, the conduction band offset ΔE_{C} may have a value less than 0.2 eV.

As shown in a valence band level E_{VI} in a flat band state in (a) of FIG. 5, the valence band offset ΔE_{V} occurs at the interface between the trapping layer TL and the channel layer CH due to the difference between the valence band level of the trapping layer TL and the valence band level of the channel layer CH. The valence band offset ΔE_{V} may have a relatively large value. According to some example embodiments, the valence band offset ΔE_{V} may be greater than the conduction band offset ΔE_{C}. According to some example embodiments, the valence band offset ΔE_{V} may be 0.5 eV or greater. According to some example embodiments, the valence band offset ΔE_{V} may be 1.0 eV or greater or may be 2.0 eV or greater.

The trapping layer TL may include the deep trap level DT therein. The deep trap level DT may refer to an energy state resulting from a defect existing in the trapping layer TL, and, in particular, refers to an energy state of a trap site having a relatively large energy difference from the valence band of the trapping layer TL. The valence band offset ΔE_{V} may have a value large enough for holes to be trapped in the deep trap level DT in the trapping layer TL during a program operation.

(b) of FIG. 5 schematically shows a band diagram of the trapping layer TL and the channel layer CH in a program operation.

As shown in (b) of FIG. 5, a gate voltage V_{G}, which is a negative voltage, is applied to the word line WL in the program operation. The gate voltage V_{G} applied to the word line WL in the program operation is referred to as a program voltage V_{P}. According to some example embodiments, as the program voltage V_{P} having a negative value is applied to the word line WL, the energy band of the gate insulation layer GI and energy bands of the trapping layer TL and the channel layer CH may be bent or curved, and holes may move from the channel layer CH toward the trapping layer TL. Holes may be trapped in the deep trap level DT inside the trapping layer TL due to the valence band offset ΔE_{V} having a relatively large value, and thus, holes may be stored in the trapping layer TL.

(c) of FIG. 5 schematically shows a band diagram of the trapping layer TL and the channel layer CH in an erase operation.

As shown in (c) of FIG. 5, the gate voltage V_{G}, which is a positive voltage, is applied to the word line WL in an erase operation. The gate voltage V_{G} applied to the word line WL in the erase operation is referred to as an erase voltage V_{E}. According to some example embodiments, as the erase voltage V_{E} having a positive value is applied to the word line WL, the energy band of the gate insulation layer GI and the energy bands of the trapping layer TL and the channel layer CH may be bent or curved, and electrons may move from the channel layer CH toward the trapping layer TL. Due to the conduction band offset ΔE_{C} having a relatively small value, electrons may move into the trapping layer TL and be re-combined with holes stored in the trapping layer TL, and thus, holes may be removed.

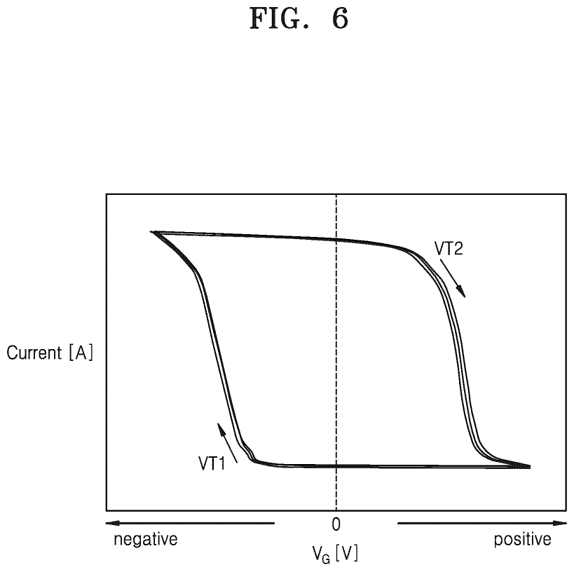

FIG. 6 is a graph schematically showing a voltage-current curve of an integrated circuit device according to an example embodiment.

Referring to FIG. 6, when the gate voltage V_{G} is decreased from a positive value to a negative value, a current rapidly increases at a first threshold voltage VT1 and then becomes saturated. Thereafter, when the gate voltage V_{G} is increased again from the negative value to a positive value, the current rapidly decreases at a second threshold voltage VT2 and then becomes saturated. At this time, the first threshold voltage VT1 and the second threshold voltage VT2 have different values, and the first threshold voltage VT1 and the second threshold voltage VT2 may correspond to a program voltage and an erase voltage, respectively.

According to the example embodiments described above, charges are stored by trapping holes by using a deep trap level in the trapping layer TL. In a programmed state in which holes are stored in the trapping layer TL, a threshold voltage shift is induced by holes present in a deep trap site, and thus, the hysteresis of a voltage-current curve as shown in FIG. 6 may be obtained. The memory unit ME may exhibit a relatively large hysteresis or a difference between the first threshold voltage VT1 and the second threshold voltage VT2, and thus, the memory unit ME may have a relatively large memory window. Furthermore, due to a relatively large energy level difference between the deep trap level DT and the valence band, the memory unit ME may exhibit excellent retention characteristics.

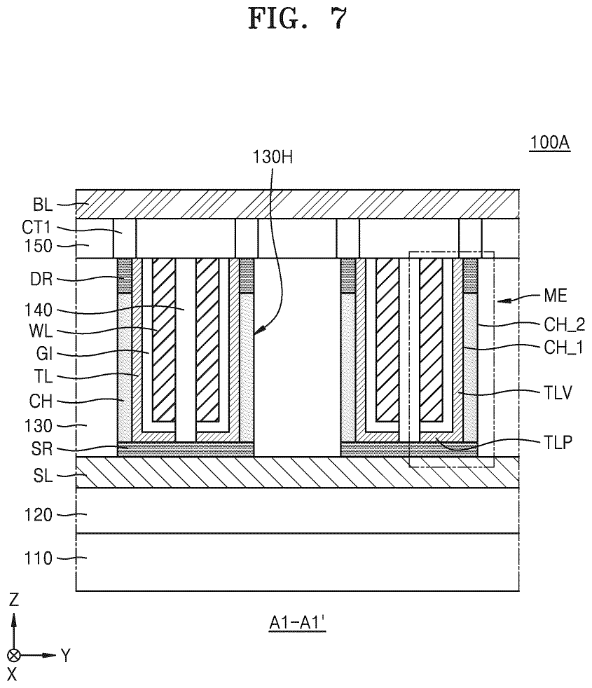

FIG. 7 is a cross-sectional view of an integrated circuit device 100A according to an example embodiment.

Referring to FIG. 7, the plurality of word lines WL may each have a rectangular cross-section, and sidewalls of the word lines WL contacting the filling insulation layer 140 may be mutually aligned with sidewalls of the gate insulation layer GI and sidewalls of the horizontal extension TLP of the trapping layer TL. The width of an upper portion of the filling insulation layer 140, e.g., the width of a portion of the filling insulation layer 140 disposed between two word lines WL adjacent to each other may be substantially identical to the width of a lower portion of the filling insulation layer, e.g., a portion of the filling insulation layer 140 disposed between two trapping layers TL adjacent to each other.

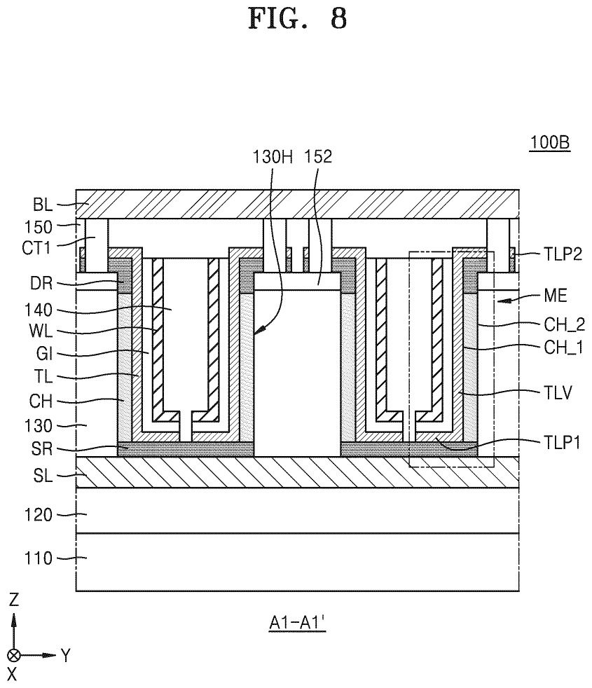

FIG. 8 is a cross-sectional view of an integrated circuit device 100B according to an example embodiment.

Referring to FIG. 8, an etch stop layer 152 may be disposed on the mold insulation layer 130, and the drain region DR and the trapping layer TL may continuously extend from the sidewall (e.g., side boundary) of the opening 130H of the mold insulation layer 130 onto the top surface of the etch stop layer 152. Therefore, the drain region DR may have an inverted L-shaped vertical cross-section. The trapping layer TL may include a first horizontal extension TLP1 disposed on the source region SR, the vertical extension TLV extending in the vertical direction Z from the first horizontal extension TLP1 and contacting the first sidewall CH_1 of the channel layer CH, and a second horizontal extension TLP2 disposed on the top surface of the drain region DR.

The bit line contact CT1 may be disposed to penetrate through the upper insulation layer 150, the second horizontal extension TLP2 of the trapping layer TL, and the drain region DR. As shown in FIG. 8, the bottom surface of the bit line contact CT1 may contact the top surface of the etch stop layer 152. According to other example embodiments, the bit line contact CT1 may not completely penetrate through the drain region DR, and thus, the bit line contact CT1 may be formed to a height that the bottom surface of the bit line contact CT1 is surrounded by the drain region DR and does not contact the top surface of the etch stop layer 152.

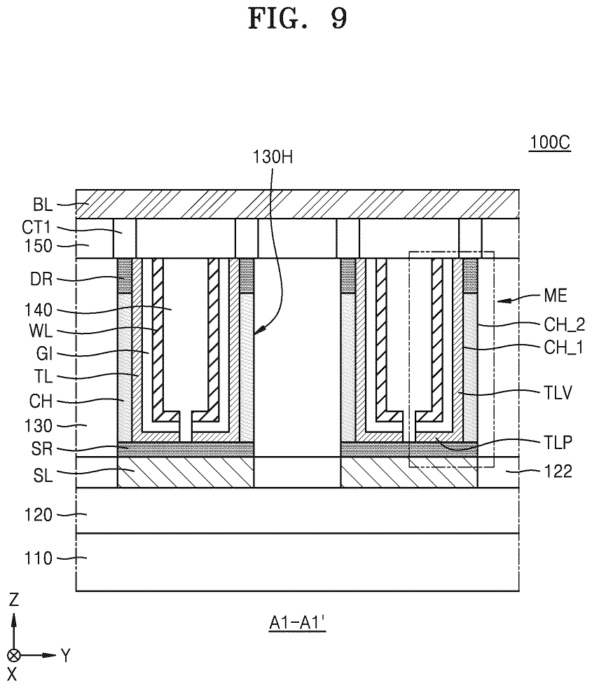

FIG. 9 is a cross-sectional view of an integrated circuit device 100C according to an example embodiment.

Referring to FIG. 9, the plurality of source lines SL may extend in the first horizontal direction X, and on the plurality of source lines SL, the plurality of word lines WL may extend in the first horizontal direction X and the plurality of bit lines BL may extend in the second horizontal direction Y. As the plurality of bit lines BL are arranged perpendicularly to the plurality of source lines SL, a NOR type array may be configured.

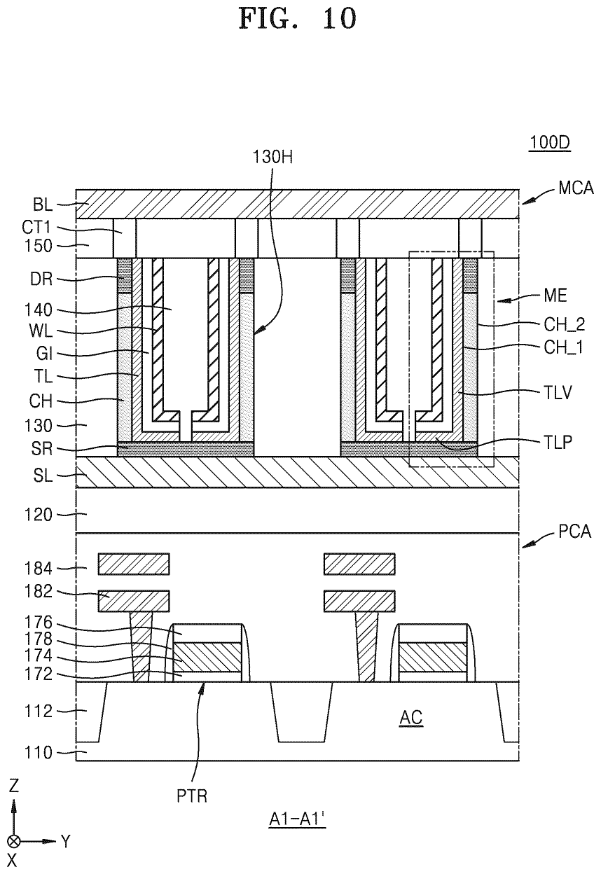

FIG. 10 is a cross-sectional view of an integrated circuit device 100D according to an example embodiment.

Referring to FIG. 10, the integrated circuit device 100D may have a cell over periphery (COP) structure. For example, the peripheral circuit area PCA may be disposed on the substrate 110, and the cell array area MCA may be disposed at a higher vertical level than that of the peripheral circuit area PCA.

A device isolation layer 112 defining an active region AC may be disposed on the substrate 110. A peripheral circuit transistor PTR may be disposed on the active region AC. The peripheral circuit transistor PTR may include a gate dielectric layer 172, a peripheral circuit gate electrode 174, a gate capping pattern 176, and a gate spacer 178 sequentially stacked on the substrate 110.

The gate dielectric layer 172 may include at least one selected from among a silicon oxide film, a silicon nitride film, a silicon oxynitride film, an oxide/nitride/oxide (ONO) film, and a high-k dielectric film having a dielectric constant higher than that of the silicon oxide film. The peripheral circuit gate electrode 174 may include a doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOₓ, RuOₓ, or a combination thereof. The gate capping pattern 176 and the gate spacer 178 may include silicon nitride.

A peripheral circuit wiring layer 182 electrically connected to the peripheral circuit transistor PTR may be disposed on the substrate 110, and an interlayer insulation layer 184 covering the peripheral circuit wiring layer 182 may be disposed on the substrate 110.

On the interlayer insulation layer 184, the lower insulation layer 120, the plurality of source lines SL, the plurality of bit lines BL, and the plurality of memory units ME arranged at intersections of the plurality of source lines SL and the plurality of bit lines BL may be arranged.

FIG. 10 shows an example structure in which the peripheral circuit transistor PTR is formed on the substrate 110 and the cell array area MCA is formed at a level higher than that of the peripheral circuit transistor PTR. However, unlike the structure shown in FIG. 10, a structure in which the peripheral circuit transistor PTR is formed on an additional substrate (not shown), the cell array area MCA is formed on the substrate 110, and the additional substrate and the substrate 110 are bonded to each other through copper-to-copper bonding may be implemented.

Also, FIG. 10 shows an example in which the plurality of memory units ME are arranged in a cross-point arrangement at the same vertical level in the cell array area MCA. However, unlike that shown in FIG. 10, the integrated circuit device 100D may include a plurality of memory units ME arranged on a first vertical level and a plurality of memory units ME arranged on a second vertical level that is higher than the first vertical level. Also, the plurality of memory units ME arranged on the second vertical level may share the bit line BL with the plurality of memory units ME arranged on the first vertical level, or the plurality of memory units ME arranged at the second vertical level may be connected to a separate additional bit line BL.

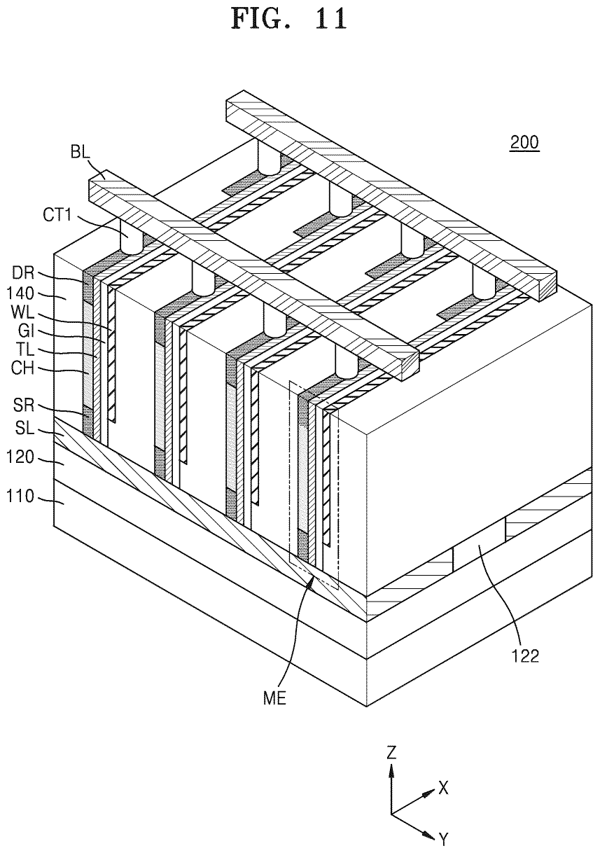

FIG. 11 is a perspective view of an integrated circuit device 200 according to an example embodiment.

Referring to FIG. 11, the source region SR, the channel layer CH, and the drain region DR may be sequentially arranged on the source line SL in the vertical direction Z. The channel layer CH may have a relatively large height in the vertical direction Z. Sidewalls of the source region SR, the channel layer CH, and the drain region DR may be aligned with one another.

The trapping layer TL, the gate insulation layer GI, and the word line WL may be sequentially arranged on the sidewalls of the source region SR, the channel layer CH, and the drain region DR. In the integrated circuit device 200, unit memory units ME in each of which the trapping layer TL, the gate insulation layer GI, and the word line WL are sequentially arranged on one sidewall of the channel layer CH may be repeatedly arranged in the second horizontal direction Y. Because one word line WL is disposed on the sidewall of one channel layer CH, the integrated circuit device 200 may be referred to as a single gate type vertical channel trapping type transistor.

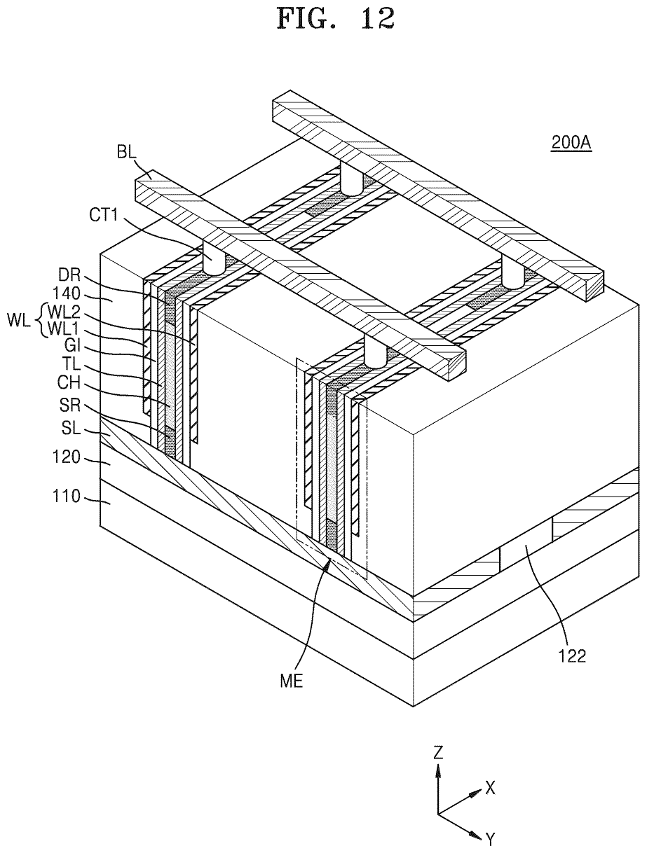

FIG. 12 is a perspective view of an integrated circuit device 200A according to an example embodiment.

Referring to FIG. 12, the source region SR, the channel layer CH, and the drain region DR may be sequentially arranged on the source line SL in the vertical direction Z. The trapping layer TL, the gate insulation layer GI, and the first word line WL1 may be sequentially arranged on a first sidewall of the channel layer CH. The trapping layer TL, the gate insulation layer GI, and the second word line WL2 may be sequentially arranged on a second sidewall of the channel layer CH.

Because the first word line WL1 and the second word line WL2 are arranged on both sidewalls of the channel layer CH, the integrated circuit device 200A may be referred to as a dual gate type vertical channel trapping type transistor.

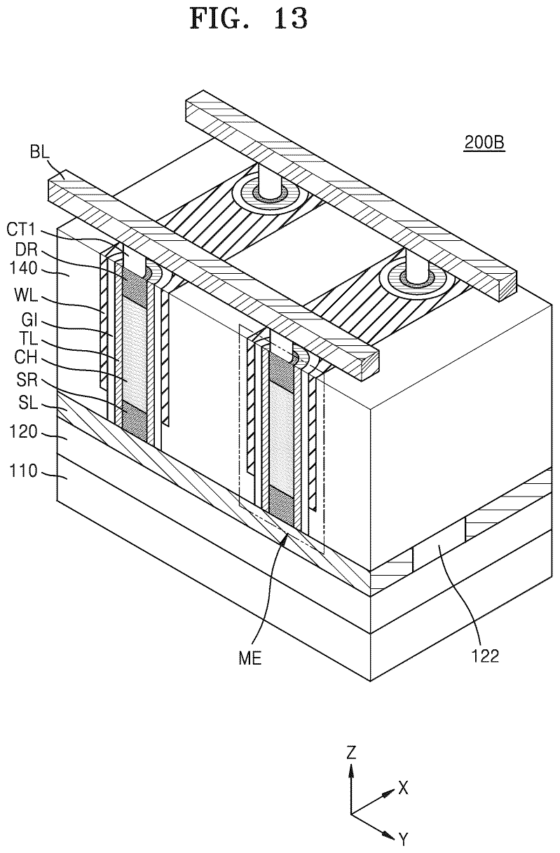

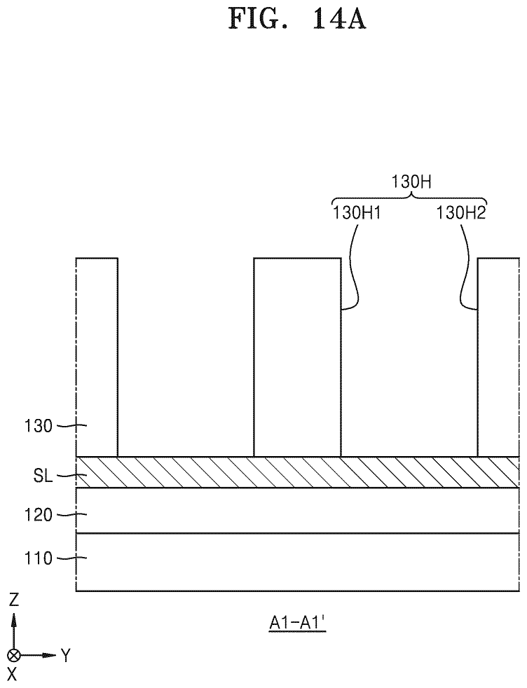

FIG. 13 is a perspective view of an integrated circuit device 200B according to an example embodiment.

Referring to FIG. 13, the word line WL may be disposed to surround four sidewalls of the channel layer CH, and the trapping layer TL and the gate insulation layer GI may be arranged between the channel layer CH and the word line WL.

Because the word line WL is disposed to surround the four sidewalls of the channel layer CH, the integrated circuit device 200B may be referred to as a gate all-around type vertical channel transistor.

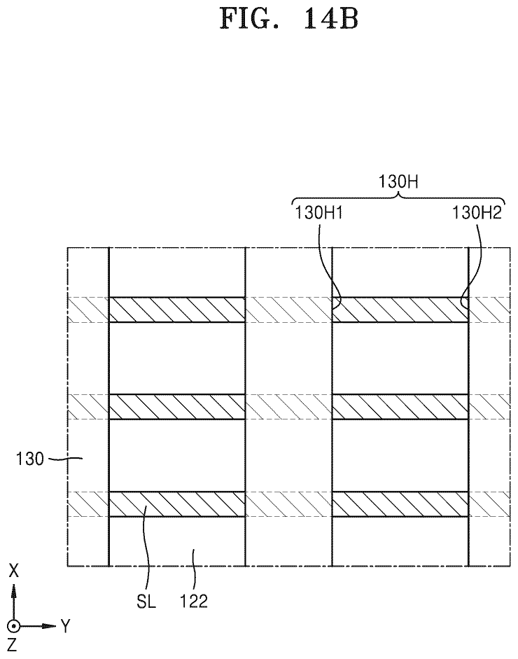

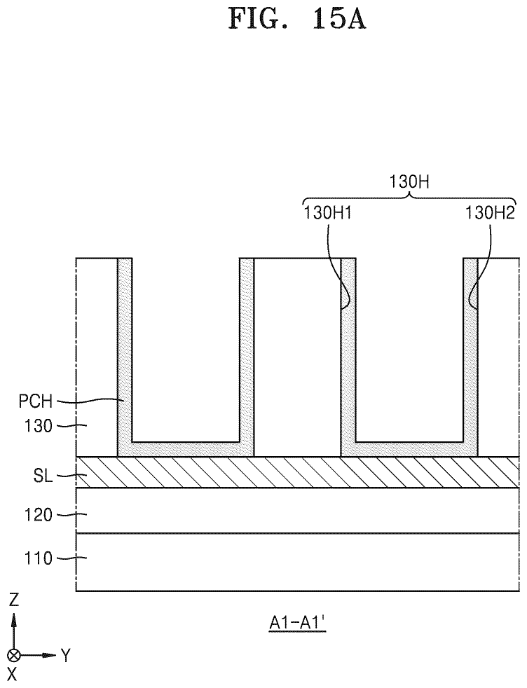

FIGS. 14A to 20B are schematic views of a method of manufacturing the integrated circuit device 100, according to an example embodiment. In detail, FIGS. 14A, 15A, 16A, 17A, 18A, 19A, and 20A are cross-sectional views of structures formed during a manufacturing process taken along a line A1-A1′ of FIG. 3, and FIGS. 14B, 15B, 16B, 17B, 18B, 19B, and 20B are top views of FIGS. 14A, 15A, 16A, 17A, 18A, 19A, and 20A, respectively.

Referring to FIGS. 14A and 14B, the lower insulation layer 120 is formed on the substrate 110. Thereafter, the plurality of source lines SL extending in the second horizontal direction Y may be formed on the lower insulation layer 120, and the first insulation layer 122 filling spaces between the plurality of source lines SL (refer to FIG. 3) may be formed.

Thereafter, the mold insulation layer 130 may be formed on the plurality of source lines SL and the first insulation layer 122. The mold insulation layer 130 may be formed to have a relatively large height in the vertical direction Z and may include at least one of silicon oxide, silicon nitride, and silicon oxynitride.

Thereafter, a mask pattern (not shown) may be formed on the mold insulation layer 130, and a plurality of openings 130H may be formed by using the mask pattern as an etching mask. The top surfaces of the source lines SL may be exposed at the bottom of the plurality of openings 130H. The plurality of openings 130H may each extend in the first horizontal direction X and include a first sidewall (e.g., a first side boundary) 130H1 and a second sidewall (e.g., a second side boundary) 130H2 opposite to each other.

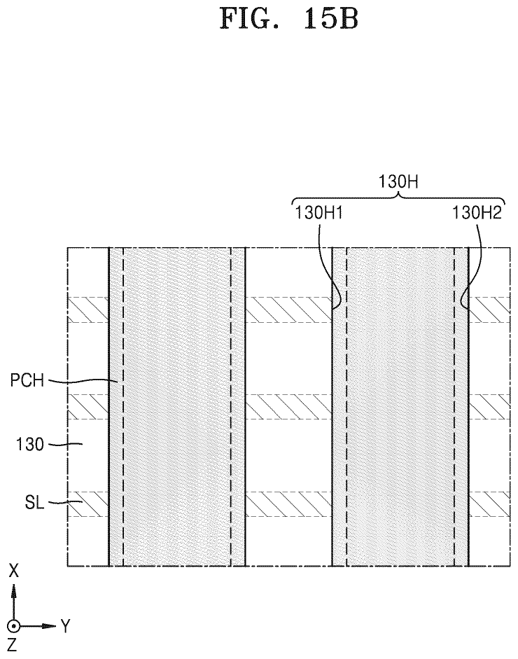

Referring to FIGS. 15A and 15B, a preliminary channel layer PCH may be formed on the inner wall (e.g., boundary) of the opening 130H of the mold insulation layer 130. The preliminary channel layer PCH may be conformally formed on the top surface of the mold insulation layer 130 and on the inner wall (e.g., boundary) of the opening 130H of the mold insulation layer 130. The preliminary channel layer PCH may have a U-shaped vertical cross-section.

According to some example embodiments, the preliminary channel layer PCH may be formed on the top surface of the mold insulation layer 130 and on the inner wall (e.g., boundary) of the opening 130H, the interior of the opening 130H may be filled with a sacrificial layer (not shown), and then the upper side of the preliminary channel layer PCH may be removed so that the top surface of the mold insulation layer 130 is exposed. Therefore, the preliminary channel layer PCH may remain only on the sidewall (e.g., side boundary) of the opening 130H of the mold insulation layer 130 and at the bottom of the opening 130H, the preliminary channel layer PCH may not be disposed on the top surface of the mold insulation layer 130, and the top surface of the mold insulation layer 130 and the top surface of the preliminary channel layer PCH may be arranged on the same plane.

According to some example embodiments, the preliminary channel layer PCH may be include at least one of polysilicon, silicon germanium, and a 2-dimensional material (e.g., hexagonal boron nitride, a transition metal dichalcogenide, or graphene). According to some example embodiments, the preliminary channel layer PCH may be formed through a chemical vapor deposition process or an atomic layer deposition process.

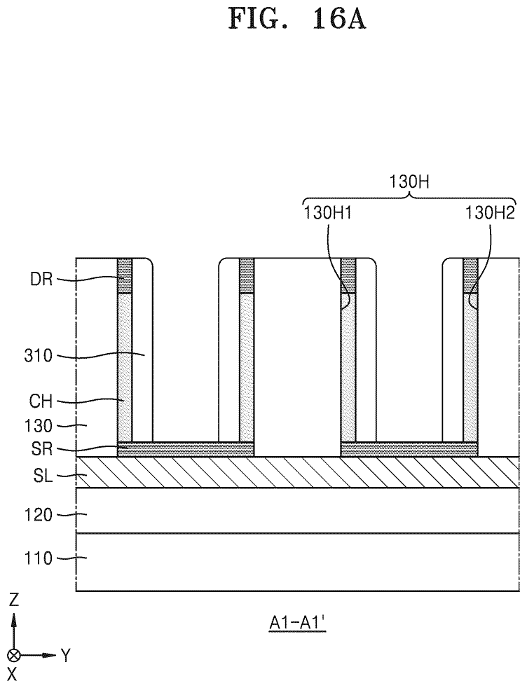

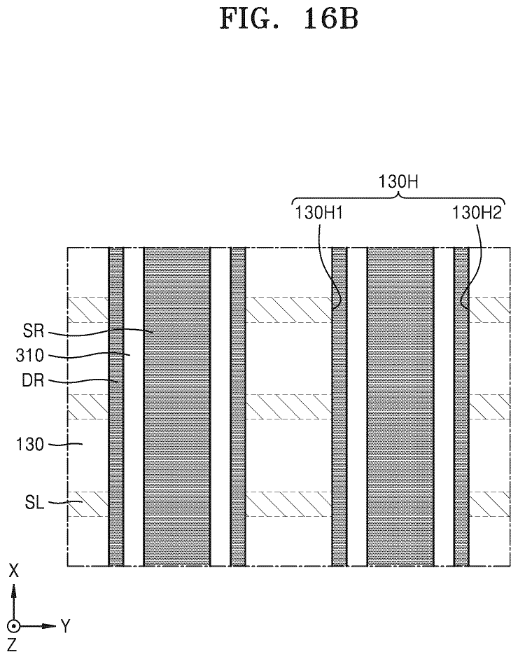

Referring to FIGS. 16A and 16B, an insulation layer (not shown) may be formed on the mold insulation layer 130 and the preliminary channel layer PCH, and an anisotropic etching process may be performed on the insulation layer to form the a spacer 310 on the inner wall of the opening 130H of the mold insulation layer 130.

According to some example embodiments, the spacer 310 may expose the top surface of the preliminary channel layer PCH disposed on the sidewall (e.g., side boundary) of the opening 130H and the top surface of the preliminary channel layer PCH disposed at the bottom of the opening 130H without covering them.

Thereafter, an ion implantation process may be performed on exposed surfaces of the preliminary channel layer PCH, thereby forming the source region SR on a portion of the preliminary channel layer PCH disposed at the bottom of the opening 130H of the mold insulation layer 130 and forming the drain region DR on a portion of the preliminary channel layer PCH disposed on the sidewall (e.g., an upper portion of the side boundary) of the opening 130H. According to some example embodiments, the source region SR and the drain region DR may be regions densely doped with a p-type impurity.

In addition, the drain region DR may be formed by implanting impurity ions from the top surface of the mold insulation layer 130 to a certain height, and a portion of the preliminary channel layer PCH disposed under the drain region DR may be covered by the spacer 310, and thus, impurity ions may not be implanted thereto.

According to some example embodiments, when the source region SR and the drain region DR include a semiconductor material doped with a p-type impurity, contact resistance of the source region SR and the drain region DR may be low as compared to a source region and a drain region of a vertical channel transistor having a channel layer including an oxide semiconductor according to a comparative example. Thus, a vertical channel transistor including the source region SR and the drain region DR according to the above example embodiment may exhibit excellent electrical characteristics.

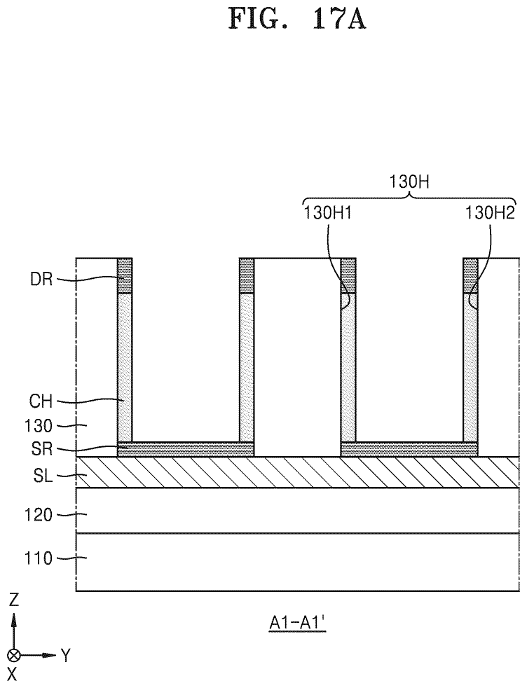

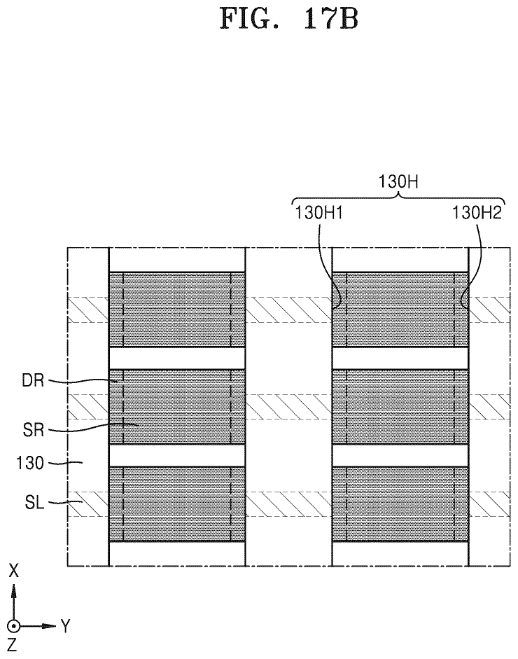

Referring to FIGS. 17A and 17B, the spacer 310 may be removed, and a mask pattern (not shown) extending in the second horizontal direction Y may be formed on the preliminary channel layer PCH. Thereafter, the plurality of channel layers CH may be formed by removing portions of the preliminary channel layer PCH by using the mask pattern as an etch mask. In the process of removing the portions of the preliminary channel layer PCH, portions of the source region SR and the drain region DR may also be removed, and thus, one source region SR may be disposed at a location where one opening 130H and one source line SL overlap each other, and the channel layer CH and the drain region DR may be arranged on each end of the source region SR.

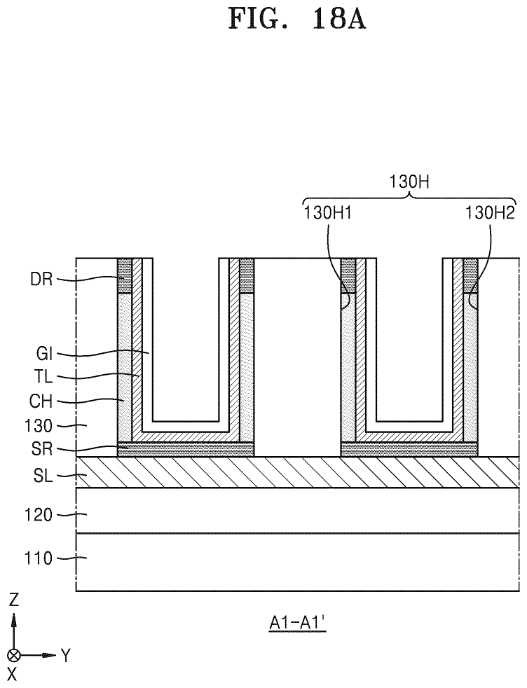

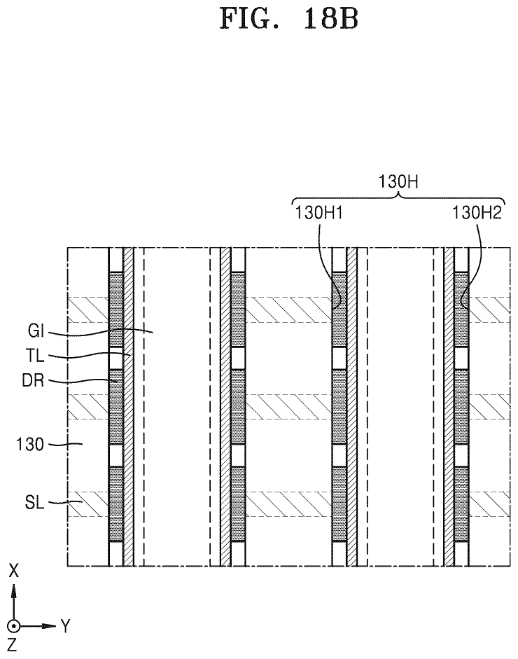

Referring to FIGS. 18A and 18B, the trapping layer TL and the gate insulation layer GI may be sequentially formed on the inner wall (e.g., boundary) of the opening 130H. The trapping layer TL may be disposed on the sidewall of the drain region DR, the sidewall of the channel layer CH, and the top surface of the source region SR and may have a U-shaped vertical cross-section. Also, the gate insulation layer GI may be conformally disposed on the trapping layer TL and may have a U-shaped vertical cross-section.

According to some example embodiments, the trapping layer TL may include at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (In_{z}O), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), or tin oxide (SnₓO).

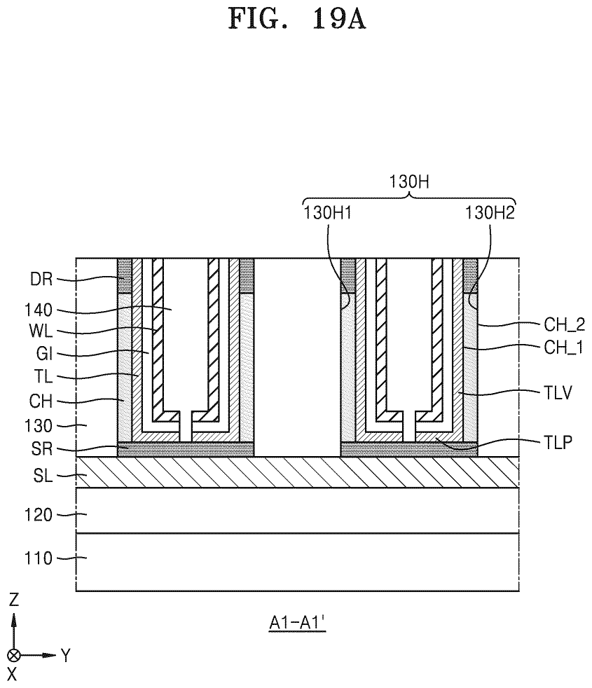

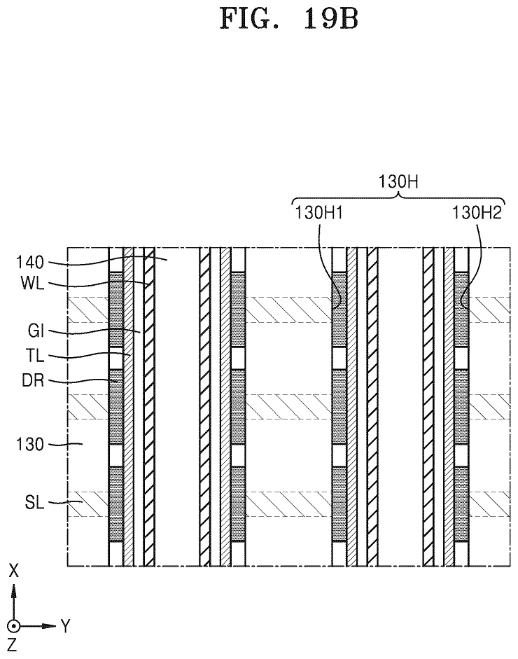

Referring to FIGS. 19A and 19B, the word line WL may be formed on the gate insulation layer GI. The word line WL may be first formed to have a U-shaped vertical cross-section on the gate insulation layer GI, and then a portion of the bottom of the word line WL may be removed by using a spacer (not shown) to separate the word line WL into two word lines WL. Therefore, in each of the plurality of openings 130H, one word line WL may be formed on the first sidewall (e.g., first side boundary) 130H1 of the opening 130H and another word line WL may be formed on the second sidewall (e.g., second side boundary) 130H2 of the opening 130H, such that the word lines WL have symmetrical shapes with respect to each other. The word line WL may have an L-shaped vertical cross-section.

Thereafter, the filling insulation layer 140 filling the plurality of openings 130H may be formed.

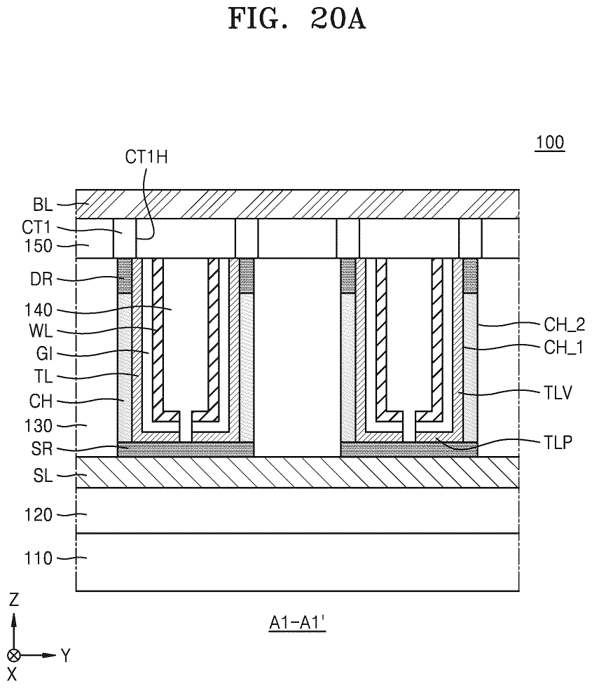

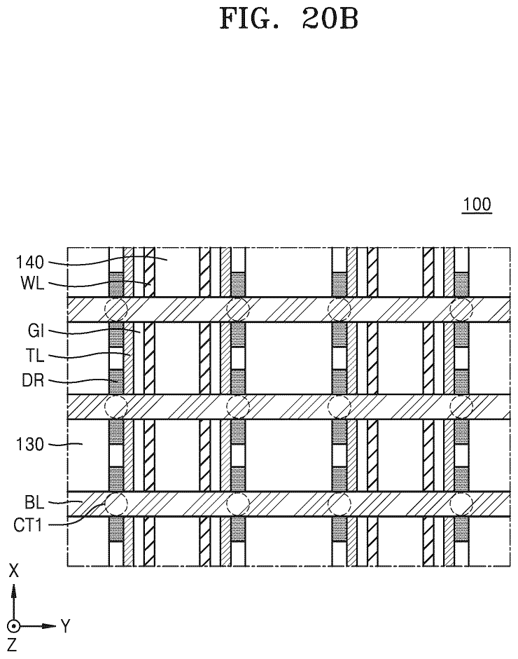

Referring to FIGS. 20A and 20B, the upper insulation layer 150 may be formed on the mold insulation layer 130 and the filling insulation layer 140, and a portion of the upper insulation layer 150 may be removed, thereby forming a bit line contact hole CT1H exposing the top surface of the drain region DR.

Thereafter, the bit line contact CT1 may be formed inside the bit line contact hole CT1H, and the bit line BL electrically connected to the bit line contact CT1 may be formed on the upper insulation layer 150.

The integrated circuit device 100 may be completely formed by performing the above-stated operations.

While the inventive concepts have been particularly shown and described with reference to some example embodiments thereof, it will be understood that various changes in form and details may be made therein without departing from the spirit and scope of the following claims.

What is claimed is:

1. An integrated circuit device comprising:
a source line extending in a first horizontal direction on a substrate;
a channel layer extending in a vertical direction perpendicular to a top surface of the substrate, the channel layer being on the source line and having a first sidewall and a second sidewall;
a trapping layer on the first sidewall of the channel layer and comprising an oxide semiconductor;
a word line on at least one sidewall of the trapping layer and extending in a second horizontal direction crossing the first horizontal direction;
a gate insulation layer between the at least one sidewall of the trapping layer and the word line; and
a bit line electrically connected to the channel layer and extending in the first horizontal direction,
wherein the channel layer has a first bandgap energy, and the trapping layer has a second bandgap energy that is greater than the first bandgap energy.

2. The integrated circuit device of claim 1, wherein a valence band offset between a valence band level of the channel layer and a valence band level of the trapping layer is 0.5 eV or greater.

3. The integrated circuit device of claim 1, wherein a valence band offset between a valence band level of the channel layer and a valence band level of the trapping layer is greater than a conduction band offset between a conduction band level of the channel layer and a conduction band level of the trapping layer.

4. The integrated circuit device of claim 1, wherein
the channel layer comprises polysilicon, silicon germanium, or a 2-dimensional material, and
the trapping layer comprises at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), or tin oxide (SnₓO).

5. The integrated circuit device of claim 1, wherein
a source region is between the channel layer and the source line, and
a drain region is between the channel layer and the bit line.

6. The integrated circuit device of claim 5, wherein the source region and the drain region comprise polysilicon doped with a p-type impurity, silicon germanium doped with a p-type impurity, or a 2-dimensional material doped with a p-type impurity.

7. The integrated circuit device of claim 5, further comprising:
a mold insulation layer covering the second sidewall of the channel layer and the source line,
wherein the trapping layer comprises a vertical extension and a horizontal extension,
the vertical extension of the trapping layer contacts the first sidewall of the channel layer, and
the horizontal extension of the trapping layer is on the source region.

8. The integrated circuit device of claim 1, wherein the word line, the gate insulation layer, and the trapping layer each have an L-shaped vertical cross-sectional shape.

9. The integrated circuit device of claim 1, wherein,
when a program voltage having a negative value is applied to the word line, the integrated circuit device is configured to allow the trapping layer to trap holes from the channel layer, and,
when an erase voltage having a positive value is applied to the word line, the integrated circuit device is configured to allow electrons to move from the channel layer to recombine with holes trapped in the trapping layer.

10. The integrated circuit device of claim 1, wherein the integrated circuit device includes a capacitor-less dynamic random-access memory (DRAM) device.

11. An integrated circuit device comprising:
a source line extending in a first horizontal direction on a substrate;
a source region on the source line and comprising a p-type impurity;
a channel layer extending from the source region in a vertical direction perpendicular to a top surface of the substrate, the channel layer having a first sidewall and a second sidewall facing each other;
a trapping layer on the first sidewall of the channel layer and on a top surface of the source region, the trapping layer comprising an oxide semiconductor;
a word line on the first sidewall of the channel layer and on the top surface of the source region, the trapping layer and a gate insulation layer being between the channel layer and the word line and between the source region and the word line;
a drain region on a top surface of the channel layer, the drain region comprising a p-type impurity; and
a bit line electrically connected to the drain region and extending in the first horizontal direction,
wherein a valence band offset between a valence band level of the channel layer and a valence band level of the trapping layer is 0.5 eV or greater.

12. The integrated circuit device of claim 11, wherein the channel layer has a first bandgap energy, and the trapping layer has a second bandgap energy that is greater than the first bandgap energy.

13. The integrated circuit device of claim 11, wherein a valence band offset between a valence band level of the channel layer and a valence band level of the trapping layer is greater than a conduction band offset between a conduction band level of the channel layer and a conduction band level of the trapping layer.

14. The integrated circuit device of claim 11, wherein
the channel layer comprises polysilicon, silicon germanium, or a 2-dimensional material, and
the trapping layer comprises at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), or tin oxide (SnₓO).

15. The integrated circuit device of claim 11, further comprising:
a mold insulation layer covering the second sidewall of the channel layer and of the source line,
wherein the trapping layer comprises a vertical extension and a horizontal extension,
the vertical extension of the trapping layer contacts the first sidewall of the channel layer, and
the horizontal extension of the trapping layer is on the source region.

16. The integrated circuit device of claim 11, wherein the word line, the gate insulation layer, and the trapping layer each have an L-shaped vertical cross-sectional shape.

17. The integrated circuit device of claim 11, wherein
when a program voltage having a negative value is applied to the word line, the integrated circuit device is configured to allow the trapping layer to trap holes from the channel layer, and
when an erase voltage having a positive value is applied to the word line, the integrated circuit device is configured to allow electrons to move from the channel layer to recombine with holes trapped in the trapping layer, and
the integrated circuit device includes a capacitor-less dynamic random-access memory (DRAM) device.

18. An integrated circuit device comprising:
a source line extending in a first horizontal direction on a substrate;
a mold insulation layer on the substrate to cover the source line and having an opening;
a source region in the opening of the mold insulation layer, the source region being on a top surface of the source line, the source region comprising a p-type impurity;
a channel layer in the opening of the mold insulation layer, the channel layer extending from the source region in a vertical direction perpendicular to a top surface of the substrate, the channel layer having a first sidewall and a second sidewall facing each other, the second sidewall being in contact with the mold insulation layer;
a trapping layer in the opening of the mold insulation layer, the trapping layer being on the first sidewall of the channel layer and on a top surface of the source region, the trapping layer comprising an oxide semiconductor;
a word line in the opening of the mold insulation layer, the word line being on the first sidewall of the channel layer and on the top surface of the source region, the trapping layer and a gate insulation layer being between the channel layer and the word line and between the source region and the word line;
a drain region in the opening of the mold insulation layer, the drain region being on a top surface of the channel layer, the drain region comprising a p-type impurity; and
a bit line electrically connected to the drain region and extending in the first horizontal direction,
wherein the channel layer comprises polysilicon, silicon germanium, or a 2-dimensional material, and
the trapping layer comprises at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), or tin oxide (SnₓO).

19. The integrated circuit device of claim 18, wherein
a valence band offset between a valence band level of the channel layer and a valence band level of the trapping layer is greater than a conduction band offset between a conduction band level of the channel layer and a conduction band level of the trapping layer, and
the valence band offset is 0.5 eV or greater.

20. The integrated circuit device of claim 18, wherein
the trapping layer comprises a vertical extension and a horizontal extension,
the vertical extension of the trapping layer contacts the first sidewall of the channel layer,
the horizontal extension of the trapping layer is on the source region, and
the word line, the gate insulation layer, and the trapping layer each have an L-shaped vertical cross-sectional shape.
